(19) United States
(12) Patent Application Publication
(10) Pub. No.: US 2006/0081188 A1
(43) Pub. Date: Apr. 20, 2006

(54) Deposition system

(75) Inventors: Hideki Komori, Tokyo (JP); Masao Sumiyoshi, Tokyo (JP); Toshio Tanaka, Tokyo (JP); Miharu Kawashima, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/107,819

(22) Filed: Apr. 18, 2005

(30) Foreign Application Priority Data
Oct. 14, 2004 (JP) 2004-299622

(51) Int. Cl. C23C 16/00

(52) U.S. Cl. 118/726

(57) ABSTRACT

A vacuum deposition system comprises a vacuum vessel, an evaporation source holder provided in the vacuum vessel for holding an evaporation substance and a holding jig provided in the vacuum vessel for holding a substrate facing the evaporation source. An adhesion-prevention member is provided at outer peripheries of the evaporation source and the holding jig along an inner wall of the vacuum vessel across a region from a position facing a lateral part of the evaporation source holder to a position facing a lateral part of the holding jig. The adhesion-prevention member is spaced apart from the inner wall of the vacuum vessel. The adhesion-prevention member includes members slanted diagonally downward from the central part side toward the inner wall. Thereby, the adhesion-prevention member prevents an evaporant from the evaporation source from adhering to the inner wall of the vacuum vessel.

### BACKGROUND OF THE INVENTION

1. Field of the Invention

The present invention relates to a vacuum deposition system preferably used for thin film formation on a surface of a subject material such as a crystal wafer, and relates particularly to improvement of an adhesion-prevention member for preventing evaporants from directly adhering to an inner wall of a vacuum vessel or the like.

2. Description of the Related Art

In general, a vacuum deposition system for forming a thin film on a surface of a subject material (i.e. subject substrate) such as a crystal wafer has a vacuum vessel and an evaporation source holder provided in the vacuum vessel. The subject substrate is held by an umbrella-like holding jig, which is removably provided above the evaporation source holder in the vacuum vessel, and is vacuum deposited. Conventionally, an adhesion-prevention member constructed from adhesion-prevention plates has been provided along the inner wall of the vacuum vessel for trapping evaporation particles, in order to prevent a portion of the evaporation particles (i.e. evaporation atoms, evaporation molecules and the like) from the evaporation source, which does not reach the subject substrate or the holding jig, from directly adhering to an inner wall of the vacuum vessel or the like. (See for example, page 1 and FIG. 2 of Japanese Unexamined Pat. Application Publication No. 2003-55754).

In such a conventional vacuum deposition system, the evaporation particles, which do not reach the subject substrate or the umbrella-like holding jig, adhere forming a film to a broad region of the adhesion-prevention plate. When air is leaked into the vacuum vessel, gas (mainly H₂O) is absorbed into this film. In the next deposition, due to radiation heat from the evaporation source or the like, the gas absorbed into this film is emitted to inside the vacuum vessel. It leads to problems that a degree of vacuum in the vacuum vessel is not stable or a composition of residual gas in the vacuum vessel is changed, and thereby characteristics of the thin film to be deposited are changed. Further, as deposition and air leaking are repeated several times, the film accumulating along the adhesion-prevention plate becomes thick, and an amount of the absorbed gas becomes increased. Therefore, a film quality of the thin film to be deposited on the subject substrate immediately after honing of the adhesion-prevention plate is different from a quality thereof after deposition is repeated several times. It leads to a problem that variations are generated among deposition batches, and a constant quality cannot be obtained.

Further, it has been a problem that the film, which adheres to and accumulates on the surface of the adhesion-prevention member, is exfoliated to become dust, which is scattered in the vacuum vessel and the scattered dust adheres to the surface of the subject substrate, leading to a cause of defects. In order to solve such a problem, there is a method of shortening interval of honing or replacement cycles for the adhesion-prevention member, or a method of baking inside of the vacuum vessel. However, in order to perform such a method, it is inevitable to stop deposition and take the time considerably. In result, it leads to a problem that productivity is decreased.

### SUMMARY OF THE INVENTION

In view of the foregoing problems of the related arts, it is an object of the present invention to provide a vacuum deposition system capable of preventing deterioration in quality of a film deposition (thin film formation) due to reemission of gas absorbed into an adhesion-prevention member, preventing pollution in a vacuum vessel, and preventing generation of defects due to adhesion of dust to a subject substrate without decreasing productivity.

A vacuum deposition system according to the present invention comprises a vacuum vessel, an evaporation source holder provided in the vacuum vessel for holding an evaporation source and a holding jig provided in the vacuum vessel for holding a subject substrate to face to the evaporation source. Further, an adhesion-prevention member is provided at outer peripheries of the evaporation source and the holding jig along an inner wall of the vacuum vessel across a region from a position facing to a lateral part of the evaporation source holder to a position facing to a lateral part of the holding jig. The adhesion-prevention member is spaced apart from the inner wall of the vacuum vessel. The adhesion-prevention member is constructed by using a plurality of louver members slanted diagonally down below from the central part side to the outer side. Thereby, the adhesion-prevention member prevents an evaporant from the evaporation source from adhering to the inner wall of the vacuum vessel.

In the present invention, the adhesion-prevention member is provided so that the adhesion-prevention member blocks in outer peripheries of an evaporation source and a holding jig across a region from a position facing to a lateral part of the evaporation source to a position facing to a lateral part of the holding jig, and is estranged from an inner wall of the vacuum vessel. The adhesion-prevention member is constructed by using a plurality of louver members slanted diagonally down below from a central part side to the inner wall of the vacuum vessel. Thereby, it is possible to prevent deterioration in quality of deposition due to reemission of gas absorbed into the adhesion-prevention member, to prevent pollution in the vacuum vessel, and to prevent generation of defects due to adhesion of dust to the subject substrate without decreasing productivity.

### BRIEF DESCRIPTION OF THE DRAWINGS

FIG. 1 shows a vertical cross sectional view of a vacuum deposition system according to a first embodiment of the invention.

FIG. 2 is an enlarged elevation view of one example of an adhesion-prevention member having inclined passage honeycomb body structure.

FIG. 3 is an enlarged elevation view of another example of an adhesion-prevention member having a louver-like multiplate structure.

FIG. 4 is an enlarged cross sectional view for explaining an adhesion of an accumulative film to a louver member and exfoliation action thereof.

FIG. 5 is a vertical cross sectional view showing substantial parts of a vacuum deposition system according to a second embodiment of the invention.

FIG. 6a shows an enlarged horizontal cross sectional view of a conventional adhesion-prevention member (or adhesion-prevention plate) or the louver member.

FIG. 6b shows an enlarged horizontal cross sectional view of a louver member of an adhesion-prevention member provided with mirror finish according to a third embodiment of the invention.

FIG. 7 shows a vertical cross sectional of a vacuum deposition system according to a fourth embodiment of the invention.

### DETAILED DESCRIPTION OF THE PREFERRED EMBODIMENTS

### First Embodiment

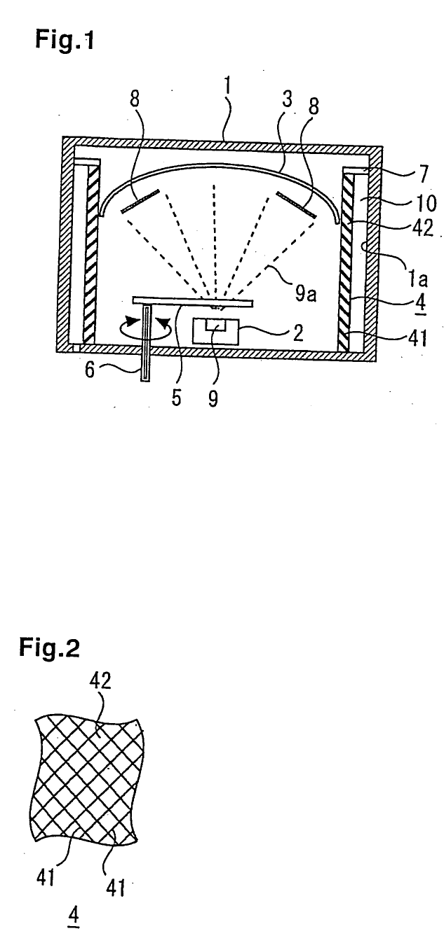

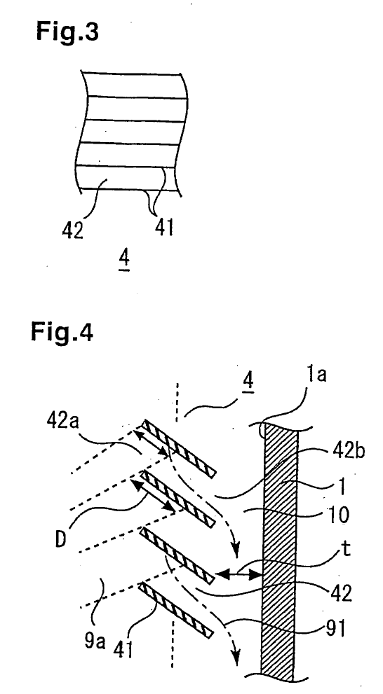

FIGS. 1 through 4 are views explaining a vacuum deposition system according to a first embodiment of-the present invention. FIG. 1 is a vertical cross section showing, by a model, a substantial construction. FIG. 2 is an enlarged elevation view showing, by a model, an example of a case that an adhesion-prevention member is formed of an inclined passage honeycomb body structure. FIG. 3 is an enlarged elevation view showing, by a model, an example of a case that an adhesion-prevention member is formed of a louver-like multiplate structure. FIG. 4 is an enlarged cross section explaining, by a model, an adhesion of an accumulative film to a louver member and exfoliation action thereof. As shown in the figures, this vacuum deposition system comprises a vacuum vessel 1 in the shape of, for example, an approximately quadrangular cylinder, which communicates with or is connected with an unshown exhaust means. An evaporation source holder 2 is provided in a central part at a bottom of this vacuum vessel 1. A holding jig 3 is formed in the shape of, for example, an umbrella or a dome, which is removably provided above the center of the vacuum vessel 1 so that the holding jig 3 faces to this deposition source holder 2.

The holding jig 3 is intended to hold a subject substrate 8 as a subject material such as a crystal wafer so that the subject substrate 8 faces to the deposition source holder 2. In order to prevent evaporation particles from passing through the holding jig 3 and adhering to a ceiling part of the vacuum vessel 1 and to make a distance from the deposition source 2 approximately constant independent of a position on the holding jig 3, the holding jig 3 is in the shape of an umbrella or a dome. The subject substrate 8 is held at an inner part of the holding jig 3, and located inside the solid angle of an evaporation particle flow from the evaporation source holder 2. That is, when viewed from the evaporation source holder 2, the subject substrate 8 is located inside a curved surface formed by the holding jig 3.

The topside of the evaporation source holder 2 is formed as a crucible for holding an evaporation substance 9. The evaporation source holder 2 generates an evaporation particle flow 9a of the evaporation substance 9 in a certain solid angle as shown by dotted lines in the figure by a known method such as electron beam and resistance heating. Further, a shutter plate 5 for controlling the evaporation particle flow 9a from the evaporation source 2 is attached to an end of a shutter shaft 6 which passes through the bottom part of the vacuum vessel 1 rotatably while maintaining airtightness. This shutter plate 5 is in the shape of a fan in view of the top face side. The shutter plate 5 can be moved alternatively between a position directly above the evaporation source holder 2 and a position deviating from the position directly above the evaporation source holder 2 by rotating the shutter shaft 6 fixed to a part approximately corresponding to a pivot of the fan.

Further, in the vacuum vessel 1, an adhesion-prevention member 4 is removably attached to the vacuum vessel 1 by a holding claw 7. This adhesion-prevention member 4 is a cylindrical member, which is formed by using a plurality of louver members 41 of, for example, the inclined passage honeycomb body structure exemplified in FIG. 2, or the louver-like multiplate structure exemplified in FIG. 3. The adhesion-prevention member 4 is provided so that the adhesion-prevention member 4 blocks in outer peripheries of the evaporation source holder 2 and the holding jig 3 across a region from a position facing to a lateral part of the evaporation source holder 2 to a position facing to a lateral part of the holding jig 3, and a gap (or clearance) 10 is provided by making a given clearance t from an inner wall 1a of the vacuum vessel 1. Further, the adhesion-prevention member 4 is formed so that a passage 42, which is formed by adjacent louver members 41 and is heading from inside to outside is slanted so that the passage 42 confronts a diagonally lower part from the central part side of the vacuum vessel 1 to the inner wall 1a face of the vacuum vessel 1. Further, the adhesion-prevention member 4 is formed so that a passage 42, which is formed by adjacent louver members 41, is slanted downward from the central part side of the vacuum vessel 1 to the inner wall 1a of the vacuum vessel 1.

As for the louver member 41, various materials of general metals including alloys such as, for example, SUS (stainless), Al, Ti, Cu, and Ni can be preferably used without particular limitations. Engineering plastic or the like can be used according to a material used for the deposition source. Further, when the foregoing louver member 41 is formed of the louver-like structure, the louver member 41 can be formed by one piece of a louver member by, for example, spirally layering the member. With reference to FIG. 4, the passage 42 has an inner opening 42a that opens to an inner periphery side of the adhesion-prevention member 4. The passage 42 has an outer opening 42b that opens to an outer periphery side of the adhesion-prevention member 4. The accumulative film drops along a dropping route 91. Further, the clearance t of the foregoing gap part 10 is selected, for example, in the range about from 0.5 cm to 2 cm in a general vacuum deposition system. However, the size is not limited to this range.

Next, an operation of the first embodiment constructed as above will be described. The subject substrate 8 is fixed on the holding jig 3. The subject substrate 8 and the holding jig 3 are together set inside the vacuum vessel 1 by using the holding claw 7. Meanwhile, a given evaporation substance 9 selected as appropriate is loaded in the evaporation source holder 2. The shutter plate 5 is set to the position directly above the evaporation source 2 (i.e. closing state) by operating the shutter shaft 6, and inside of this vacuum vessel 1 is exhausted by the unshown exhaust means. Subsequently, the evaporation source 2 is heated to generate the evaporation particle flow 9a from the evaporation substance 9. When generation of the evaporation particle flow 9a is stabilized, the shutter plate 5 is set to the position deviating from the position directly above the evaporation source 2 (i.e. opening position) by operating the shutter shaft 6, and deposition to the subject substrate 8 is started.

The part above the foregoing evaporation source holder 2 is shrouded like an umbrella by the holding jig 3 under which the subject substrate 8 is fixed. In the lateral directions and in the diagonally upper direction of the evaporation source 2, the adhesion-prevention member 4 is provided across the region from the position facing to the lateral part of the evaporation source 2 to the position facing to the periphery face part of the holding jig 3. Therefore, the evaporation particle flow 9a from the evaporation substance 9 always reaches the subject substrate 8 fixed on the holding jig 3, the holding jig 3 or the adhesion-prevention member 4 in the vicinity of the inner opening 42a at a wall face part shown by arrow D. As a result, a thin film is formed on the surface of the subject substrate 8. When a thin film having a given thickness is formed on the subject substrate 8, the shutter plate 5 is set to the closing state, heating the evaporation source 2 is stopped, air is leaked into the vacuum vessel 1, and the subject substrate 8 is taken out together with the holding jig 3 from the vacuum vessel 1. When deposition for the next batch is performed subsequently, the foregoing operation is repeated.

In the foregoing first embodiment, evaporation particles among the evaporation particle flow 9a from the deposition substance 9, incoming from the inner opening 42a into the passage 42 of the adhesion-prevention member 4, are trapped and blocked by the surface of this louver member 41 at the D part (FIG. 4). Since the adhesion-prevention member 4 is provided, accumulation of the film on the inner wall 1a of the vacuum vessel 1 is prevented, and emission of the absorbed gas from the inner wall 1a of the vacuum vessel 1 is avoided. Thus, vacuum deposition can be performed under a stable degree of vacuum and a stable gas composition. In addition, since the film adhering to the inner wall 1a of the vacuum vessel 1 is decreased down to almost zero, exfoliation and scattering of the film from this inner wall 1a can be prevented, and adhesion of the exfoliated film to the subject substrate 8 is prevented.

The evaporation particles, which adhere to the D part of the surface of the louver member 41 forming the inner opening 42a of the adhesion-prevention member 4 and turn into an accumulative film, are naturally exfoliated when a film thickness thereof reaches a certain amount. In the structure of the adhesion-prevention member 4 of the invention, the passage 42 formed by the adjacent louver members 41 is slanted diagonally downward in relation to the inner wall 1a of the vacuum vessel 1. In addition, the gap part (or clearance) 10 is provided between the adhesion-prevention member 4 and the inner wall 1a of the vacuum vessel 1. Therefore, as shown by a model with the dashed line 91 in FIG. 4, the accumulative film drops in the direction of the outer opening 42b, that is, drops diagonally down below in relation to the inner wall 1a of the vacuum vessel 1. Then, the accumulative film is collected at the bottom of the gap part 10 between the adhesion-prevention member 4 and the inner wall 1a of the vacuum vessel 1. Therefore, the exfoliated film is prevented from scattering to the area of evaporation particle flow, and the exfoliated film is prevented from adhering to the subject substrate 8. Resultantly, adverse effects to the process and the quality can be kept to the minimum.

Further, in the structure of the adhesion-prevention member 4 of the invention, the louver member 41 can become a thin plate. Therefore, the louver member 41 becomes easily strained by changes in temperatures of the adhesion-prevention member 4 due to radiation heat mainly from the evaporation source holder 2 in the course from deposition start to deposition completion, and the accumulative film of the evaporation particles adhering mainly to the D part of the surface becomes easily exfoliated. Further, it is also preferable to use a memory metal for the louver member 41 constructing the adhesion-prevention member 4 and a backing (not shown), which holds the louver member 41. In this case, the component member of the adhesion-protection member 4 can be more largely strained by the changes in temperatures due to the foregoing radiation heat, and exfoliation of the accumulated evaporation particles can be further accelerated.

As described above, according to the first embodiment of the invention, the following effects can be obtained.

1) It is possible to prevent accumulation of the film on the inner wall 1a of the vacuum vessel, inhibit emission of the absorbed gas from the inner wall 1a of the vacuum vessel, and perform vacuum deposition under the stable degree of vacuum and the stable composition of the residual gas without decreasing productivity. In result, characteristics of the thin film to be deposited become stable.

2) The amount of the film adhering to the inner wall 1a of the vacuum vessel is decreased down to approximately zero. Therefore, exfoliation and scattering of the film from this inner wall is prevented, and adhesion of the exfoliated film to the subject substrate 8 is prevented.

3) Even if the accumulative film of the evaporation particles trapped by the wall face of the adhesion-prevention member 4 is exfoliated and departs from the wall face, the exfoliated accumulative film drops in the gap part (or clearance) 10 between the adhesion-prevention member 4 and the inner wall 1a of the vacuum vessel 1. Therefore, adverse effects to the process and the quality can be kept to the minimum.

4) Further, in the structure of the adhesion-prevention member 4 of the invention, the louver member 41 constructing the adhesion-prevention member 4 can become a thin plate. Therefore, the louver member 41 becomes easily strained by changes in temperatures of the adhesion-prevention member 4 due to radiation heat mainly from the evaporation source 2 in the course from deposition start to deposition completion, and the accumulative film of the evaporation particles adhering to the louver member 41 becomes easily exfoliated.

5) Even if deposition and air leaking are repeated, the film accumulating on the louver member 41 does not become thick, and the emission amount of the absorbed gas is not increased.

In result, the replacement and maintenance cycle of the adhesion-prevention member 4 can be expanded, and vacuumization and evacuation time after maintenance becomes shortened. In result, the operation rate and productivity can be improved.

### Second Embodiment

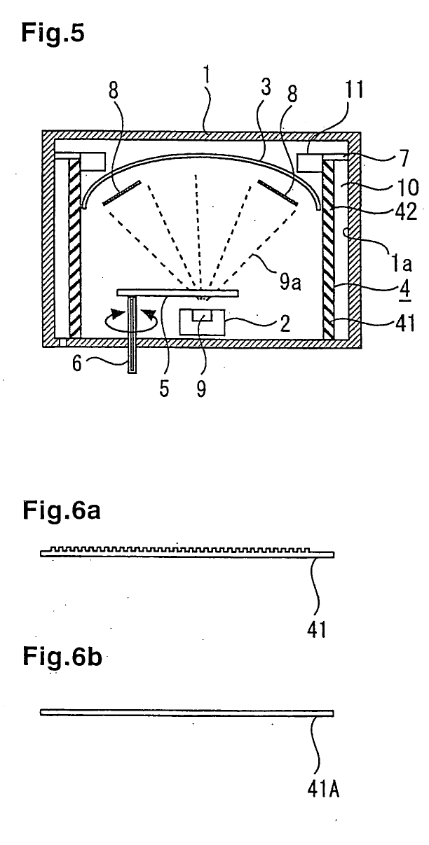

FIG. 5 is a vertical cross section showing, by a model, a construction of a substantial part of a vacuum deposition system according to a second embodiment of the invention. In this second embodiment, a strain provision means 11 is provided for generating strain for the adhesion-prevention member 4. A strain provision means 11 can be a heating means such as a heater for heating the adhesion-prevention member 4 and/or a vibration provision means such as an ultrasonic device for vibrating the adhesion-prevention member 4 (detailed illustrations are omitted for the both). Since other constructions are similar to of the foregoing first embodiment, descriptions thereof will be omitted.

In the second embodiment as constructed above, after deposition on the subject substrate 8 is completed and before air is introduced, the strain provision means 11 constructed from the heating means such as the heater and /or the vibration provision means such as the ultrasonic device is operated, and physical (thermal or mechanical) strain is generated in the adhesion-prevention member 4. Thereby, a body of the louver member 41 and the like constructing the adhesion-prevention member 4 is actively strained. The accumulative film of the evaporation particles adhering to the wall of the adhesion-prevention member 4, i.e. to the surface of the louver member 41, becomes further easily exfoliated. Therefore, a state that the amount of the accumulative film of the evaporation particles is small can be always maintained. In result, the absorbed gas is decreased, which brings about good effects to the deposition process.

As above, according to the second embodiment, after deposition completion and before air opening, the strain provision means 11 is operated to previously removing the accumulative film of the evaporation particles adhering to the surface of the louver member 41. Thereby, the state of the film accumulating on the surface of the louver member 41 can be controlled. Then, even if deposition and air leaking are repeated, the emission amount of the absorbed gas can be further simply controlled. Therefore, further good effects can be brought about for decreasing the absorbed gas.

### Third Embodiment

FIGS. 6a and 6b are comparative views for explaining a state of the surface of the louver member used for a vacuum deposition system. FIG. 6a is an enlarged horizontal cross section showing, by a model, a general adhesion-prevention member (adhesion-prevention plate) or the louver member 41. FIG. 6b is an enlarged horizontal cross section showing, by a model, a louver member 41A provided with mirror finish according to the third embodiment of the invention. Except that a whole surface of a component material for the adhesion-prevention member 4 is provided with the mirror finish, constructions of this third embodiment are similar to that of the foregoing first and second embodiments. Therefore, descriptions thereof will be omitted.

As explained above, in the vacuum deposition system of this third embodiment, the whole surface of the component material for the adhesion-prevention member 4 is provided with the mirror finish. Therefore, anchor effects of the accumulative film of the deposition particles to the surface of the louver member 41A are significantly decreased, and the accumulative film becomes further easily exfoliated. Therefore, compared to the first and second embodiments, residual of the accumulative film (or residual portion) on the surface of the adhesion-prevention member 4 is decreased, and further good effects are brought about for decreasing the absorbed gas. In the foregoing description, the case that the whole surface of the component material for the adhesion-prevention member 4 such as the louver member 41A is provided with the mirror finish has been described. However, when only the face including the D part of FIG. 4 in the louver member 41A, that is, the face confronting the evaporation source, is provided with the mirror finish, reasonable effects can be obtained.

### Fourth Embodiment

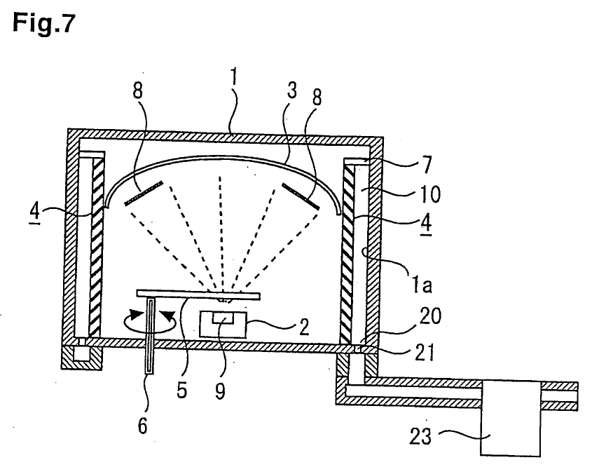

FIG. 7 is a vertical cross section showing, by a model, a construction of a substantial part of a vacuum deposition system according to a fourth embodiment of the present invention. The vacuum deposition system of this fourth embodiment is provided with an opening 21 at a bottom part 20 of the gap portion (or clearance) 10 between the inner wall 1a of the vacuum vessel 1 and the adhesion-prevention member 4. The opening 21 communicates with an unshown vacuum exhaust means, and a filter 23 on a downstream side of the opening 21, that is, between the opening 21 and the unshown vacuum exhaust means. Since other constructions are similar to that of the foregoing first embodiment, descriptions thereof will be omitted.

In the vacuum deposition system of the fourth embodiment constructed as above, it is possible that an exfoliated piece of the accumulative film from the surface of the adhesion-prevention member 4, which is collected on the bottom portion 20 of the gap part (or clearance) 10 between the inner wall 1a of the vacuum vessel 1 and the adhesion-prevention member 4 is discharged outside the vacuum vessel 1, and the discharged exfoliated piece is trapped by the filter 23. When the foregoing exfoliated piece of the accumulative film is discharged, it is desirable that the discharge is performed immediately after batch change when a pressure inside the vacuum vessel 1 is close to air pressure, or during the process when the pressure inside the vacuum vessel 1 is set to about 0.1 to 0.05 MPa by gas not including moisture (H₂O) such as nitrogen gas and dry air.

As described above, according to the fourth embodiment, adverse effects of emission of the absorbed gas from the collected exfoliated piece of the accumulative film can be kept to the minimum by discharging the exfoliated piece of the accumulative film in the vacuum vessel 1 outside of the vacuum vessel 1 as appropriate. Further, it is also preferable that the construction is made so that a heating means (not shown) such as a heater is provided on the foregoing bottom portion 20, and the exfoliated piece of the accumulative film is heated. In this case, it is possible that gas such as H₂O is prevented from being absorbed into the exfoliated piece of the accumulative film in the vacuum vessel 1 particularly in air opening. Therefore, emission of the absorbed gas during the deposition process can be significantly reduced.

In the foregoing descriptions of the embodiments, the case that the adhesion-prevention member is formed of the inclined passage honeycomb body structure or the louver-like multiplate structure has been described. However, the invention is not limited to these structures. Further, the vacuum vessel 1 is described in the shape of the approximately quadrangular cylinder. However, it is needless to say that the invention is not limited to this shape.

1. A vacuum deposition system comprising:
a vacuum vessel having an inner wall, a top portion, and a lower portion located below the top portion;
an evaporation source holder located in said vacuum vessel in the lower portion for holding an evaporation substance;
a holding jig located in said vacuum vessel for holding a substrate above and facing said evaporation source holder; and
an adhesion-prevention member located at outer peripheries of said evaporation source holder and said holding jig, along the inner wall of said vacuum vessel, across a region from a position facing a lateral part of said evaporation source holder to a position facing a lateral part of said holding jig, said adhesion-prevention member
being spaced by a gap from the inner wall of said vacuum vessel,
including a plurality of louver members mutually spaced from each other and slanted diagonally downwards from a top portion of each louver member closer to a central part of said vacuum vessel, to a lower portion of each louver member more remote from the central part of said vacuum vessel than the top portion of the louver member, and
preventing an evaporant from said evaporation source holder from adhering to the inner wall of said vacuum vessel.

2. The vacuum deposition system according to claim 1, wherein said louver members include a louver-like multiplate structure.

3. The vacuum deposition system according to claim 1, wherein said louver members include an inclined passage honeycomb body structure.

4. The vacuum deposition system according to claim 1, wherein said louver members have a mirror surface.

5. The vacuum deposition system according to claim 1, wherein said louver members are made of a memory metal.

6. The vacuum deposition system according to claim 1, further comprising a strain provision means for straining said adhesion-prevention member.

7. The vacuum deposition system according to claim 1, including:
an opening at a bottom part of a gap between said adhesion-prevention member and the inner wall of said vacuum vessel, said opening communicating with a vacuum exhaust device; and
a filter located between said opening and the vacuum exhaust device.

8. The vacuum deposition system according to claim 1, including heating means located at the bottom of the gap between said adhesion-prevention member and the inner wall of said vacuum vessel.

9. The vacuum deposition system according to claim 6, wherein said strain prevention means is a heater attached to said adhesion-preventing member for heating and expanding said adhesion-prevention member to exfoliate particles deposited on said adhesion-prevention member.

10. The vacuum deposition system according to claim 6, wherein said strain prevention means is a vibrator attached to said adhesion-preventing member for vibrating said adhesion-prevention member to exfoliate particles deposited on said adhesion-prevention member
